(19) United States
(12) Patent Application Publication
(10) Pub. No.: US 2009/0053896 A1
(43) Pub. Date: Feb. 26, 2009

(54) Copper polishing slurry

(75) Inventors: Bin Hu, Mesa, AZ (US); Richard Wen, Mesa, AZ (US); Deepak Mahulikar, N. Kingston, RI (US)

Correspondence Address: Paul D. Greeley;Ohlandt, Greeley, Ruggiero & Perle, L.L.P., 10th Floor, One Landmark Square, Stamford, CT, 06901-2682, US

(73) Assignee: Planar Solutions, LLC

(21) Appl. No.: 12/221,864

(22) Filed: Aug. 7, 2008

Related U.S. Application Data
(60) Provisional application No. 60/964,082, filed on Aug. 9, 2007.

(51) Int. Cl. H01L 21/304; C09K 13/00

(52) U.S. Cl. 438/693; 252/79.1; 257/E21.239

(57) ABSTRACT

A water-soluble polymer is effective as a removal rate enhancer in a chemical mechanical polishing slurry to polish copper on semiconductor wafers or other copper laid structures, while keeping the etching rate low. The slurry may also include soft particles and certain metal chelating agents, or combinations thereof. The slurry can also comprise an abrasive particle, an organic acid, and an oxidizer.

### CROSS-REFERENCE TO RELATED APPLICATIONS

The present application claims priority to U.S. Provisional Application No. 60/964,082, filed on Aug. 9, 2007.

### BACKGROUND OF THE DISCLOSURE

1. Field of the Disclosure

The present disclosure relates to a composition and method for chemical mechanical polishing (CMP) of copper on semiconductor wafers or other copper laid structures. The method polishes copper with high removal rates, low defectivity, high planarity and ultra-smooth surface finishing.

2. Description of Related Art

Chemical mechanical planarization (or chemical mechanical polishing, CMP) is a process for planarization of semiconductor substrates. Achieving global planarization of a wafer is critical in the CMP process. All of the metal layers on the wafer must be polished atomically flat so that micro-lithography can be carried out and high device yields can be obtained. Global planarity, usually expressed in the term of within wafer nonuniformity (WIWNU), is calculated as the one standard deviation of all the measured data points of either the film thickness of interest, or the thickness difference before and post polishing, or in terms of removal rate. Some introductory references on CMP are “Polishing Surfaces for Integrated Circuits”, by B. L. Mueller and J. S. Steckenrider, Chemtech, February, 1998, pages 38-46; and H. Landis et al., Thin Solids Films, 220 (1992), page 1.

Any defects on the film surface generated during the CMP process are undesirable. Killer defects such as deep scratches, corrosion, residual particles and chemistries including carbon residue, possibility introduced through slurry formulation, resulting in reduced electrical performance and lowered die yield, are unacceptable by the semiconductor manufacturers. The sum of all the defects (SOD) is one way to estimate the severity of defectivity after the CMP process. Another critical parameter used to describe the quality of the CMP process is topography, or dishing—depression of the larger copper trenches or vias, and erosion—loss of the dielectrics in high density copper line areas. Minimized topography is mandated by the lithographic process in semiconductor manufacturing.

CMP of copper containing layers presents some very unique and difficult challenges. The chemical component of a CMP composition can form a passivation layer on the copper, changing the copper to a copper oxide. The copper oxide has different mechanical properties, such as density and hardness, than metallic copper and passivation changes the polishing rate of the abrasive portion. Furthermore, the mechanical component of many currently available CMP compositions typically abrades elevated portions of copper, and the chemical component then dissolves the abraded material. The chemical component can also passivate recessed copper areas, minimizing dissolution of those portions.

Another important consideration in CMP slurry selection is “passive etch rate,” which is the rate at which copper is dissolved by the chemical component alone. The passive etch rate should be significantly lower than the removal rate when both the chemical component and the mechanical component are involved. A large passive etch rate leads to dishing of the copper trenches and copper vias.

Removal of the bulk copper film at the highest possible rate is desired for throughput and productivity purpose. The high removal rate needs to be achieved with relatively low mechanical forces for advanced technology nodes in semiconductor manufacturing. It relies largely on the chemical activity of the slurry. One of the limiting factors in choosing aggressive chemistry is the resulting static etch rate on the same film. The ideal chemistry gives the highest removal rate while achieving the lowest etch rate, besides other performance restrictions.

Accordingly, there is a need for a CMP composition, or slurry, that addresses all of these concerns.

### SUMMARY OF THE DISCLOSURE

According to the present disclosure, there is a slurry composition that addresses the above mentioned conflict between high removal rate and low etch rate for semiconductor structures having copper lines, and produces copper surfaces with high planarity, low defectivity and very low surface roughness.

In the present disclosure, it has been discovered that the addition of a water soluble polymer, for example a hydrolyzed styrene and maleic anhydride co-polymer resin, in combination with abrasive particles, organic acids, corrosion inhibitors, or oxidants, gives very high copper removal rate, low etch rate, low defectivity, low WIWNU and superior copper surface finish. This disclosure also provides a composition that helps reduce topography in copper CMP.

In a first embodiment, the present disclosure provides a chemical-mechanical polishing slurry, having a plurality of abrasive particles, an oxidizer, and a water-soluble polymer.

In another embodiment, the present disclosure provides a chemical-mechanical polishing slurry having a plurality of abrasive particles, an oxidizer, at least one water-soluble polymer selected from the group consisting of polyorganic acids, hydrolyzable anhydrides, hydrolyzable nitriles, polyimides, and polyamines, a plurality of soft particles selected from the group consisting latex beads, fluoro-polymer beads, and combinations thereof, at least one copper chelating agent selected from the group consisting of ethylenediaminetetracetic acid, N-hydroxyethyl-ethylenediaminetriacetic acid, nitrilotriacetic acid, diethylenetriaminepentacetic acid, citric acid, malonic acid, glycine, alanine, or serine, and an ammonium salt.

In another embodiment, the present disclosure provides a method of polishing a copper-containing substrate comprising contacting the substrate with a slurry composition. The slurry composition comprises a plurality of abrasive particles, an oxidizer, and at least one water-soluble polymer selected from the group consisting of polyorganic acids, hydrolyzable anhydrides, hydrolyzable nitriles, polyimides, and polyamines.

### DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is photograph of a copper substrate after being polished with the slurries of the present disclosure.

### DETAILED DESCRIPTION OF THE DISCLOSURE

It has been found that the inclusion of a water-soluble polymer enhances copper removal rate while suppressing static etch rate, and also leaves an extremely smooth surface finish with very low defect counts. Without being bound by theory, it is believed that the water-soluble polymer of the present disclosure forms a complex with the copper oxide passivation layer on the substrate. This complex softens the oxide layer, which can then be removed by the mechanical components of the CMP slurry. It was previously thought that the use of such a polymer, particularly in high concentrations, would adversely affect the ability of the CMP slurry to polish the copper substrate, and would instead bond to or form a layer on the top of the substrate.

The water-soluble polymer can be selected from the group consisting of poly-organic acids, hydrolyzable anhydrides or nitriles, polyimides, polyamines, any polymer with acids or amines as side groups, in non-ionized or ionized (salt) form, and combinations thereof. The polymer can be a homopolymer or a copolymer. The polymer can be a polyorganic acid, and can be in a hydrolyzed form. In one embodiment, the polymer is a hydrolyzed styrene and maleic anhydride co-polymer resin. The polymer may be present in a range from about 1 ppm to 10% by weight, from about 1 ppm to 1% by weight, or from about 1 ppm to 1000 ppm by weight. In one particular embodiment, the polymer is present in an amount between about 50 ppm to about 200 ppm, and in another the polymer is present in an amount of about 100 ppm.

The inclusion of a soft particle in the CMP slurry of the present disclosure can also help reduce the topography of the target substrate. This soft particle can comprise any polymer beads insoluble in the slurry, such as latex beads, polytetrafluoroethylene (PTFE) beads, any other synthetic or natural resin beads, or combinations thereof. In one embodiment, the soft particles are a fluoro-polymer material, such as PTFE. The soft particles can be sized about 50 nm to about 1000 nm in diameter, or between about 200 nm to about 500 nm. The soft particles can be present in a concentration of between about 5 ppm to about 1% by weight, and also in a concentration of between about 10 ppm to about 1000 ppm by weight.

The slurry of the present disclosure can further comprise an ammonium salt, which significantly increases the copper removal rate. The ammonium salt can help to dissolve the byproducts of the CMP process, which can cause damage to the substrate if left untreated. The salt can be formed between ammonia and any organic or inorganic acids, or between urea and any acid. In one embodiment, the ammonium salt is selected from the group consisting of ammonium chloride, ammonium sulfate, ammonium phosphate, or ammonium propionate. The ammonium salt can be present in the range between about 0.01% to about 10% by weight, and also in the amount of about 0.1% to about 1% by weight.

The CMP slurry of the present disclosure can further comprise water, abrasive, oxidizer, corrosion inhibitor, and copper chelating agent, or any other components suited for polishing of a substrate.

The water, serving as the carrier, can help to distribute the abrasive and chemical agents so that they are in contact with the surface of the wafer, which moves against the pad in the active polishing process. The water can also clean away any byproducts resulting from chemical reactions of the copper or other films, that are dislodged either by mechanical abrasion between the surfaces or dissolution of the products. The water can also conduct and dissipate any thermal energy generated during polishing, and wet or lubricate the surfaces to be polished. Water can be from any water source. It is preferably demineralized, deionized or reverse osmosis treated.

The abrasive can, for example, be particles of silica, alumina, ceria, latex beads, resin beads, or any other inorganic or organic solids, or mixtures thereof. The abrasive can be different shapes and sizes, synthetic or naturally existing, and can have the surface of the particles modified by chemical reactions or physical treatments. An example is particles from 10 nm to 200 nm in diameter, with either narrow or wide distribution, or poly-model, or a blend of larger and smaller particles, preferably particles of 20-100 nm size. A preferred abrasive efficiently removes the oxidized copper surface under mild mechanical forces, without scratching the copper body or otherwise altering the integrity of the copper structure. Abrasives in the slurry range from between about 100 ppm to about 10% by weight, or from about 500 ppm to about 5%.

Oxidizers that can be used in the CMP slurries of the present disclosure can, for example, include hydrogen peroxide, ammonium persulfate, potassium persulfate, ferric chloride, potassium iodate, peracetic acid, other inorganic or organic peroxides, or mixtures thereof. The selection of oxidizer for a slurry body involves the understanding of the stability of the chemistries, the kinetics and thermodynamics of the reactions with copper or other films, as well as safety, cost and availability of the oxidizer. Oxidizers can be present from about 0.1 wt % to about 5 wt %, and also from about 0.5 wt % to about 2 wt %.

One undesirable side effect of CMP is the introduction of potential corrosion to the metal structures or the handling systems. Therefore, a corrosion inhibitor can be included in the slurry. One such corrosion inhibitor can be benzotriazole (BTA). In addition, many derivative forms of small or macro-molecules of BTA and triazole, as well as amino or carboxylic compounds that can form complexing products with metals, preferably in the insoluble form of such complexing products, are also used as corrosion inhibitors. The results of using corrosion inhibitors in the slurry reach beyond the sole purpose of metal surface protection. The corrosion inhibitor can also help manipulate the formation of the passivation film on the copper surface, providing a way to balance removal rates and planarization. Corrosion inhibitors can be used in the range of about 5 ppm to about 5% by weight, and also from about 10 ppm to about 1% by weight.

In some circumstances, any chemical that modifies the properties of water, such as surface tension, polarity, thermal conductivity and fluidity, can play a role in the manipulation of the properties of the slurry of the wafer surface, affecting planarization, removal rate, WIWNU, defectivity and surface finish. Likewise, any chemical that interrupts the oxidation of copper by the oxidizer, alters the quality, formation speed and properties of the resulting oxidation products, providing means to control removal rates, uniformity, topography and surface protection can also affect these properties.

In another embodiment, a copper chelating agent can help the reduction of topography of the substrate to be polished. The chelating agent can be any molecule containing multiple carboxylic or amino or the combination of both functional groups. Some examples are ethylenediaminetetracetic acid (EDTA), N-hydroxyethyl-ethylenediaminetriacetic acid (NHEDTA), nitrilotriacetic acid (NTA), diethylenetriaminepentacetic acid (DTPA), citric acid, malonic acid, glycine, alanine, serine, among others, or combinations thereof. In one embodiment, the chelating agent is a carboxylic acid of at least three functional groups, and is present in a concentration range of 5 ppm to 5% by weight. The concentration can also be from about 10 ppm to about 1% by weight.

The slurry can have a pH of between about 2 to about 11, between about 4 and about 10, and between about 5 and about 9. Organic acids generally can be used to balance the pH of the slurry. In one embodiment, the organic acids can be selected from the group consisting of propionic, citric, or oxalic acids, or combinations thereof. The organic acid can be present in an amount of 2 wt % or less, or in an amount of about 1 wt %.

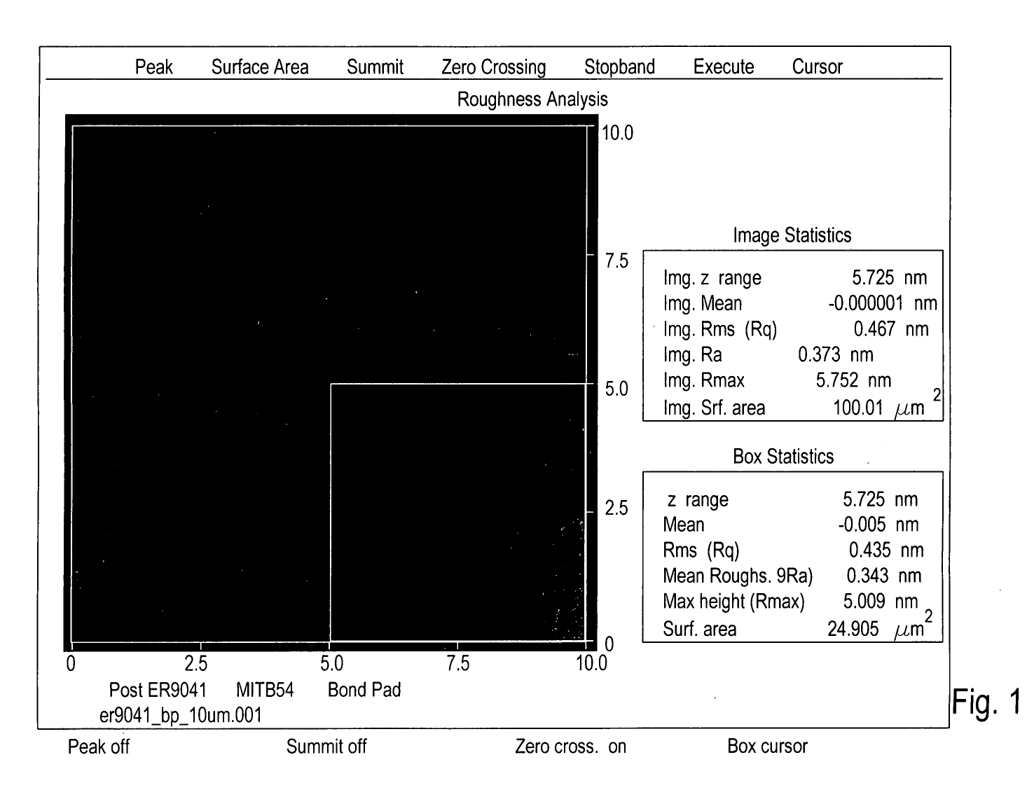

Thus, as shown in FIG. 1 and the following supporting data, the CMP slurry of the present disclosure is particularly suited for use on copper substrates. The slurry can be used for polishing off the bulk copper layer and clearing a wafer to expose the barrier under-layer and copper lines and vias, without leaving residual copper on the substrate or resulting in significant dishing or erosion. A system used in a CMP process can consist of at least a slurry, a pad, the substrate to be polished in the form of a semiconductor wafer or otherwise, and electronic and mechanical accessories to assist the execution of the polishing process.

FIG. 1 shows an image of a copper substrate after being polished, with roughness data. As shown in the “Image Statistics” window, the copper surface finish is extremely smooth by polishing with the slurry containing the water-soluble polymer. The mean roughness (Rm) as measured with AFM is about 3-4 Å, and root mean square 4-5 Å.

The following data further illustrates the advantages of the slurry of the present disclosure.

### EXAMPLES

The following data was obtained on 8″ copper blanket films. The polishing was carried out on a Mirra polisher (Applied Materials, Inc.) with IC1010 pads which were conditioned with either an ABT, 3M or Kinik conditioner. Table 1 below shows the conditions under which the following data was collected.

TABLE 1

| | Platen (RPM) | Head (RPM) | Inner Tube (psi) | Retaining Ring (psi) | Membrane (psi) | Slurry Flow (mL/min) |
|---|---|---|---|---|---|---|
| 3 psi DF | 113 | 119 | 4.1 | 4.7 | 3 | 200 |
| 2 psi DF | 113 | 119 | 2.8 | 3.5 | 2 | 200 |
| 1.5 psi DF | 113 | 119 | 2 | 2.3 | 1.5 | 200 |

Two initial slurry compositions were prepared, one with the water-soluble composition, and one without. As shown in Table 2, the passive etch rate of the slurry remains very low with or without the water-soluble polymer. In fact, the passive etch rate of the slurry is lessened by the addition of the polymer. As previously discussed, a large or increased passive etch rate can lead to dishing of the copper trenches and vias on the wafer.

TABLE 2

| | | Etching | Etching | Etch Rate |
|---|---|---|---|---|
| Trial # | Slurry | Temperature (° C.) | Time (sec) | (Å/min) |
| 1 | with Polymer | 21 | 300 | 9 |
| 2 | with Polymer | 21 | 300 | 14 |
| 3 | w/o Polymer | 21 | 300 | 23 |
| 4 | w/o Polymer | 21 | 300 | 20 |

Two additional slurry compositions were prepared, and measured for the sum of defects. As shown in Table 3, the presence of the water-soluble polymer in the slurry body also helps wafer defectivity reduction, by reducing the sum of defects.

TABLE 3

| | w/o pad clean | with pad clean |
|---|---|---|
| w/o polymer | >20000 | 700-1000 |
| with polymer | 100 | 100 |

### Examples 1-4

The data in Table 4 below shows the removal rate of copper at various concentrations of the water-soluble polymer. Example compositions 1-4 all had varying concentrations of components, but all contained colloidal silica abrasives, organic acids, corrosion inhibitors, and pH adjusters.

As can seen from this data, the removal rate of copper is dramatically enhanced upon the addition of the water-soluble polymer.

TABLE 4
Example 1 Cu RR (Å/min)

| Down Force (psi) | 0 ppm | 100 ppm |
|---|---|---|
| 3 | 6561 | 10174 |
| 2 | 2797 | 6337 |
| 1.5 | 1892 | 4474 |

Example 2 Cu RR (Å/min)

| Down Force (psi) | 0 ppm | 50 ppm | 100 ppm | 200 ppm | 1000 ppm |
|---|---|---|---|---|---|
| 3 | 7138 | 9897 | 9771 | 9449 | 2019 |

| | | |
|---|---|---|
| Down Force (psi) | 0 ppm | 100 ppm |

Example 3 Cu RR (Å/min)

| | | |
|---|---|---|
| 3 | 6372 | 8147 |
| 2 | 4031 | 4917 |
| 1.5 | 3185 | 3884 |

Example 4 Cu RR (Å/min)

| | | |
|---|---|---|
| 3 | 6783 | 7941 |
| 2 | 3361 | 4330 |
| 1.5 | 2211 | 2857 |

### Examples 5-9

Table 5 shows the effect of varying the percentages of various components of the slurry on the copper removal rate, dishing, and erosion defects. As can be seen, the inclusion of a copper chelating agent and soft particles reduces topography for patterned wafers. At a down force of 3 p.s.i., slurries without the soft particles may exhibit better copper removal rates and similar WINWU. At 1.2 p.s.i., however, slurry #2, which includes the chelating agent and the soft particles, exhibits significantly improved dishing and erosion characteristics, while maintaining favorable copper removal rates and WINWU, when compared to slurries without those components.

TABLE 5

| | | Example No. | | | | |
|---|---|---|---|---|---|---|
| | | 5 | 6 | 7 | 8 | 9 |
| Composition | Colloidal silica (%) | 0.5 | 0.5 | 0.5 | 0.5 | 0.5 |
| | Organic acid (%) | 1.0 | 1.0 | 1.0 | 1.0 | 1.0 |
| | Corrosion inhibitor, I (%) | 0.2 | 0.2 | 0.2 | 0.2 | 0.2 |
| | Polymer (ppm) | 100 | 100 | 100 | 100 | 100 |
| | Corrosion inhibitor, II (ppm) | 30 | 30 | 30 | 30 | 30 |
| | Copper Chelator (ppm) | 0 | 50 | 50 | 75 | 100 |
| | Soft particles (ppm) | 0 | 70 | 0 | 0 | 0 |
| | H2O2 (%) | 0.8 | 0.8 | 0.8 | 0.8 | 0.8 |
| | pH | 7 | 7 | 7 | 7 | 7 |

| | | | | | |
|---|---|---|---|---|---|
| Cu RR 3 psi, Å/min | 9034 | 8121 | 8605 | 8388 | 8283 |
| Std (%) 3 psi (WIWNU) | 2.13 | 3.08 | 2.91 | 3.13 | 2.89 |
| Cu RR 1.2 psi, Å/min | 2991 | 3024 | 2889 | 2433 | 1850 |
| Std (%) 1.2 psi (WIWNU) | 4.82 | 4.47 | 3.99 | 6.23 | 13.37 |
| 100 m × 100 m dishing (Å) | 1186 | 661 | 735 | 650 | 673 |
| 9 m × 1 m erosion (Å) | 223 | 108 | 153 | 116 | 196 |

### Examples 10-12

An additional set of data shown below in Table 6 shows that all of the slurries of the present disclosure provide strong copper removal rates and very low WIWNU, achieving high global planarity. The slurry without the soft particles or copper chelator has a higher copper removal rate, but the addition of the chelator and soft particles significantly improves the dishing and erosion characteristics of the copper substrate. Thus, the need for the copper chelator and soft particles can depend on the particular needs of the application.

TABLE 6

| | Example No. | | |
|---|---|---|---|
| | 10 | 11 | 12 |
| Ingredients | Without | With 50 ppm | With 50 ppm |
| | chelator or | chelator | chelator and |
| | soft particles | | 70 ppm |
| | | | soft particles |
| Cu RR 3 psi, ?/min | 7512 | 7384 | 6943 |
| Std (%) 3 psi (WIWNU) | 1.62 | 1.35 | 1.68 |
| Cu RR 1.2 psi, ?/min | 3328 | 3227 | 2329 |
| Std (%) 1.2 psi (WIWNU) | 5.09 | 4.49 | 4.06 |
| 100 πm × 100 πm dishing (?) | 636 | 496 | 386 |
| 9 πm × 1 πm erosion (?) | 91 | 83 | 54 |

While the present disclosure has been described with reference to one or more exemplary embodiments, it will be understood by those skilled in the art that various changes may be made and equivalents may be substituted for elements thereof without departing from the scope of the present disclosure. In addition, many modifications may be made to adapt a particular situation or material to the teachings of the disclosure without departing from the scope thereof. Therefore, it is intended that the present disclosure not be limited to the particular embodiment(s) disclosed as the best mode contemplated for carrying out this disclosure, but that the disclosure will include all embodiments falling within the scope of the claims.

What is claimed is:

1. A chemical-mechanical polishing slurry, comprising:
a plurality of abrasive particles;
an oxidizer; and
a water-soluble polymer.

2. The slurry of claim 1, wherein said water-soluble polymer is at least one selected from the group consisting of polyorganic acids, hydrolyzable anhydrides, hydrolyzable nitriles, polyimides, and polyamines.

3. The slurry of claim 2, wherein said water-soluble polymer is a hydrolyzed styrene and maleic anhydride co-polymer resin.

4. The slurry of claim 1, wherein said water-soluble polymer is present in an amount from about 1 ppm to 1000 ppm by weight.

5. The slurry of claim 4, wherein said water-soluble polymer is present in an amount between about 50 ppm to about 200 ppm.

6. The slurry of claim 1, further comprising a plurality of soft particles.

7. The slurry of claim 6, wherein said soft particles are selected from the group consisting of latex beads, fluoro-polymer beads, and combinations thereof.

8. The slurry of claim 7, wherein said soft particles are polytetrafluoroethylene.

9. The slurry of claim 8, wherein said soft particles are present in an amount of about 5 ppm to about 1 wt %.

10. The slurry of claim 6, further comprising a copper chelating agent.

11. The slurry of claim 10, wherein said copper chelating agent is at least one selected from the group consisting of ethylenediaminetetracetic acid, N-hydroxyethyl-ethylenediaminetriacetic acid, nitrilotriacetic acid, diethylenetriaminepentacetic acid, citric acid, malonic acid, glycine, alanine, or serine.

12. The slurry of claim 11, wherein said copper chelating agent is present in an amount of about 5 ppm to about 5% by weight.

13. The slurry of claim 1, further comprising an ammonium salt.

14. The slurry of claim 14, wherein said ammonium salt is at least one selected from the group consisting of ammonium chloride, ammonium sulfate, ammonium phosphate, or ammonium propionate.

15. The slurry of claim 13, wherein said ammonium salt is present in an amount of about 0.01% to about 10% by weight.

16. A chemical-mechanical polishing slurry, comprising:
a plurality of abrasive particles;
an oxidizer;
at least one water-soluble polymer selected from the group consisting of polyorganic acids, hydrolyzable anhydrides, hydrolyzable nitrites, polyimides, and polyamines;
a plurality of soft particles selected from the group consisting latex beads, fluoro-polymer beads, and combinations thereof;
at least one copper chelating agent selected from the group consisting of ethylenediaminetetracetic acid, N-hydroxyethyl-ethylenediaminetriacetic acid, nitrilotriacetic acid, diethylenetriaminepentacetic acid, citric acid, malonic acid, glycine, alanine, or serine; and
an ammonium salt.

17. The slurry of claim 16, wherein said water-soluble polymer is a hydrolyzed styrene and maleic anhydride co-polymer resin, present in an amount from about 1 ppm to 1000 ppm by weight.

18. The slurry of claim 16, wherein said copper chelating agent is a carboxylic acid of at least three functional groups, present in an amount from about 5 ppm to about 5% by weight.

19. A method of polishing a copper-containing substrate, comprising:
contacting the substrate with a slurry composition, the slurry composition comprising:
a plurality of abrasive particles;
an oxidizer; and
at least one water-soluble polymer selected from the group consisting of polyorganic acids, hydrolyzable anhydrides, hydrolyzable nitrites, polyimides, and polyamines.

20. The method of claim 19, wherein said slurry composition further comprises:
a plurality of soft particles selected from the group consisting latex beads, fluoro-polymer beads, and combinations thereof;
at least one copper chelating agent selected from the group consisting of ethylenediaminetetracetic acid, N-hydroxyethyl-ethylenediaminetriacetic acid, nitrilotriacetic acid, diethylenetriaminepentacetic acid, citric acid, malonic acid, glycine, alanine, or serine; and
an ammonium salt.
